(19) United States
(12) Patent Application Publication
(10) Pub. No.: US 2008/0293235 A1
(43) Pub. Date: Nov. 27, 2008

(54) COMPOUND WIREBONDING AND METHOD FOR MINIMIZING INTEGRATED CIRCUIT DAMAGE

(75) Inventor: Hector Deju, Indialantic, FL (US)

Correspondence Address: HARRIS CORPORATION;C/O DARBY & DARBY PC, P.O. BOX 770, CHURCH STREET STATION, NEW YORK, NY, 10008-0770, US

(73) Assignee: HARRIS CORPORATION, Melbourne, FL (US)

(21) Appl. No.: 11/751,849

(22) Filed: May 22, 2007

(51) Int. Cl. H01L 21/44

(52) U.S. Cl. 438/617; 257/E21.476

(57) ABSTRACT

A method is provided for creating a compound bond in a wire bonding process. The method includes forming a free air ball (804) at a first end (702) of a bonding wire (602). The method also includes determining a dimension and/or a shape of an anchored ball (406) disposed on a bonding site. The method further includes modifying a shape of the free air ball to at least partially conform to a shape of the anchored ball. This modification step also comprises modifying the shape of the free air ball in accordance with at least one of the dimension and the shape of the anchored ball. This modification step further comprises forming a concave surface (1502) on a portion of the free air ball. The method further includes bonding the free air ball to the anchored ball subsequent to modifying a shape of the free air ball.

### BACKGROUND OF THE INVENTION

1. Statement of the Technical Field

The inventive arrangements relate to a compound wire bonding method. More particularly, the present invention relates to a method for minimizing integrated circuit damage during a compound wire bonding process.

2. Description of the Related Art

A prepackaged semiconductor IC is conventionally comprised of an integrated circuit (IC) die encapsulated in a protective plastic casing. An IC die harvesting process generally involves chemically removing the protective plastic casing of the prepackaged semiconductor IC to yield a bare IC die. Once the plastic casing is removed from the semiconductor IC, interconnect wires become exposed. The interconnect wires are manually clipped leaving ball shaped portions of the interconnect wires coupled to the bare IC die. The harvested IC die will have an array of the ball shaped portions (herein after referred to as “anchored balls”) along its periphery. Thereafter, the harvested IC die can be adhesively coupled to a substrate. New wire interconnects can be created using a standard ball bonding process.

The standard compound ball bonding process generally involves: (1) threading a capillary by passing a bonding wire through a wire threading aperture of the capillary; (2) forming a free air ball (FAB) by applying heat to a portion of the bonding wire extending out of the wire threading aperture and away from the capillary; (3) capturing and centering the FAB in a chamfered aperture of the capillary; (4) lowering the capillary so that the FAB is aligned and adjacent to an anchored ball disposed on an IC die; (5) applying a downward force to the capillary; and (6) applying ultrasonic energy and heat to the FAB and the anchored ball for creating a permanent bond between the same.

One problem with the use of the standard compound ball bonding process with a harvested IC die is that the process can result in damage to one or more metallization layers of the IC die. The standard compound ball bonding process can also result in a cracking or cratering of a wafer material present below an anchored ball disposed on the IC die. Notably, damage to a metallization layer and/or a wafer material can significantly reduce a yield of a die harvesting process.

One way to minimize the risk of damage to a wafer material is to perform an alignment process. The alignment process ensures that a center of an FAB is perfectly aligned with a center of an anchored ball disposed on the IC die. This alignment process results in an equal distribution of a bonding stress over an interface surface of the anchored ball. Despite the advantages of this alignment process, it suffers from certain drawbacks. For example, the alignment between the centers of the FAB and the anchored ball is relatively difficult to achieve. This difficulty is due to equipment limitations and geometric inconsistencies of the anchored balls exposed in an IC die harvesting process.

Another way to minimize the risk of damaging a wafer material is to perform a somewhat modified compound ball bonding process. This process generally involves applying a reduced downward force to an FAB. This process also involves applying a reduced amount of ultrasonic energy to an FAB. Despite the advantages of this modified compound ball bonding process, it suffers from certain drawbacks. For example, this modified compound ball bonding process can result in an unsuccessful bonding between the FAB and an anchored ball.

Yet another way to minimize the risk of damaging a metallization layer and/or a wafer material is to alter a shape of the anchored ball by using a coining process or a ball shearing process. The coining process is performed to flatten a top of the anchored ball. In effect, a flatter and more consistent bonding surface is provided on the anchored ball. The ball shearing process is performed to remove a section of the anchored ball. As a result, a flat bonding surface is provided on the anchored ball. Despite the advantages of such a ball alteration process, it suffers from certain drawbacks. For example, this ball alteration process involves an application of a shear or compressive stress to the anchored ball disposed on the IC die. Such shear and compressive stresses can result in damage to the IC die before the compound ball bonding process is performed.

In view of the forgoing, there is a need for a method and apparatus that mitigates the risk of damaging an IC die during a compound ball bonding process. There is also a need for a compound ball bonding process absent of an IC die preparation requirement, such as a coining requirement and a ball shearing requirement.

### SUMMARY OF THE INVENTION

The invention concerns a method for creating a compound bond in a wire bonding process. The method includes forming a free air ball at a first end of a bonding wire. The method also includes modifying a shape of the free air ball to at least partially conform to a shape of an anchored ball. The anchored ball is disposed on a bonding site. The method further includes bonding the free air ball to the anchored ball subsequent to modifying a shape of the free air ball.

According to an aspect of the invention, the method also includes determining at least one of a dimension and a shape of the anchored ball prior to modifying a shape of the free air ball. The modifying step further comprises forming a concave surface on a portion of the free air ball.

According to another aspect of the invention, the method includes selecting a geometry of the concave surface based on a measured geometry of the anchored ball. The bonding step further comprises applying a controlled force and ultrasonic energy to the free air ball. The method also includes connecting a second end of the bonding wire to a substrate. The method further includes selecting the bonding wire to include an elongated conductive material formed of gold.

According to another aspect of the invention, the modifying step also comprises deforming the free air ball using a fool having a rigid surface. Thereafter, the free air ball is removed from the tool. The rigid surface is selected to include a convex projection. The tool is selected based on a measuring step which includes determining at least one characteristic of the anchored ball. The at least one characteristic is selected from the group comprising a dimension of the anchored ball and a shape of the anchored ball. The modifying step further comprises exposing the free air ball to an energetic stimulus to cause a heating of the free air ball.

### BRIEF DESCRIPTION OF THE DRAWINGS

Embodiments will be described with reference to the following drawing figures, in which like numerals represent like items throughout the figures, and in which:

FIGS. 1A-1C are collectively a flow diagram of a method for harvesting an IC die and creating wire interconnects that is useful for understanding the invention.

FIG. 2 is a perspective view of a semiconductor integrated circuit (IC) that is useful for understanding the present invention.

FIG. 3 is a perspective view of a semiconductor IC having a portion of a protective plastic casing removed therefrom that is useful for understanding the present invention.

FIG. 4 is a cross-sectional view of the semiconductor IC taken along line 4-4 of FIG. 3 that is useful for understanding the present invention.

FIG. 5 is a side view of a harvested IC die that is useful for understanding the present invention.

FIG. 6 is a partial cross-sectional view of a capillary being threaded that is useful for understanding the present invention.

FIG. 7 is a partial cross-sectional view of the capillary of FIG. 6 showing a wire which has been fully threaded.

FIG. 8 is a side view of a free air ball (FAB) formed on a tail portion of a bonding wire that is useful for understanding the present invention.

FIG. 9 is a side view of a capillary having an FAB captured and centered in a chamfered aperture that is useful for understanding the present invention.

FIG. 10 is a perspective view of a tool having a mold structure that is useful for understanding the present invention.

FIG. 11 is a side view of an FAB aligned with the mold structure of FIG. 10.

FIG. 12 is a side view of an FAB in contact with the mold structure of FIG. 10.

FIG. 13 shows the FAB in FIG. 12 being compressed against a face of the mold structure.

FIG. 14 is a side view of a dimpled free air ball (DFAB) removed from the mold structure of FIG. 10.

FIG. 15 is a side view of a capillary having a DFAB aligned with an anchored ball disposed on a harvested IC die.

FIG. 16 is a side view of a DFAB in contact with an anchored ball of a harvested IC die.

FIG. 17 shows a downward bonding force applied to a capillary, ultrasonic energy applied to a DFAB and an anchored ball, and heat applied to a DFAB and an anchored ball.

FIG. 18 is a side view of a DFAB permanently bonded to an anchored ball.

### DETAILED DESCRIPTION OF THE PREFERRED EMBODIMENTS

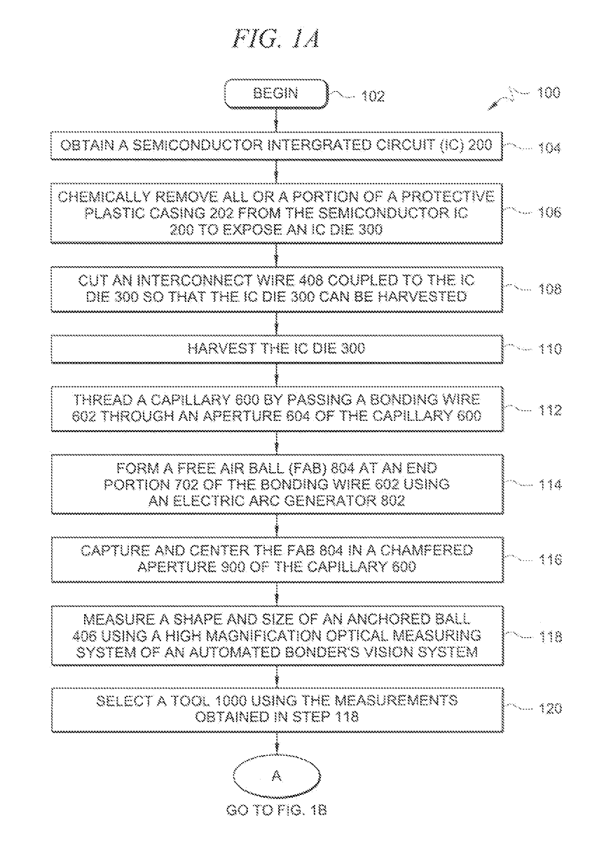

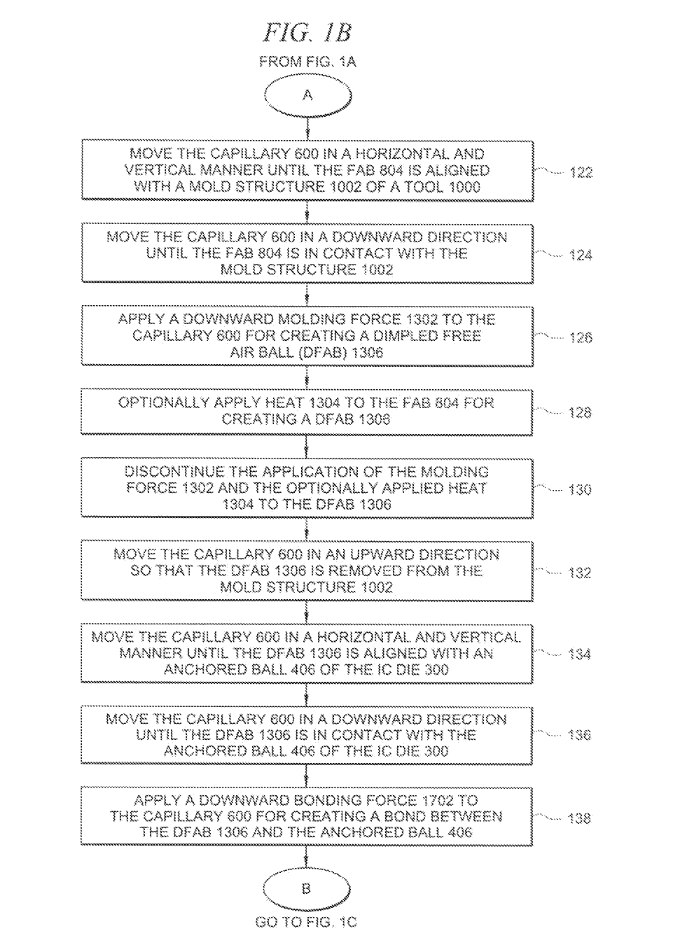

An embodiment of the present invention will now be described with respect to FIG. 1 through FIG. 18. Some embodiments of the present invention provide methods, systems, and apparatus relating to a compound bonding process. The compound bonding process is a method for attaching an interconnect (or bonding) wire on top of an existing anchored ball disposed on a bonding pad. The interconnect (or bonding) wire can have a diameter ranging from seven tenths (0.7) mils to three (3.0) mils. The bonding pads can be bond sites on a semiconductor integrated circuit (IC) die which has been harvested.

Some embodiments of the present invention also provide a method for mitigating a risk of damaging a harvested integrated circuit (IC) die during a compound bonding process. Such a method generally involves altering a shape of a free air ball (FAB) prior to permanently bonding the FAB to an anchored ball disposed on a harvested IC die. This method has several advantages. For example, an altered FAB provides a relatively larger contact area which results in a reduction of localized bonding force applied to a harvested IC die during a compound bonding process. Further, the method can be automated thereby ensuring a consistent application of a bonding force to a harvested IC die during a compound bonding process. The automated method can also ensure a consistent alignment of altered FABs and anchored balls throughout various compound bonding processes.

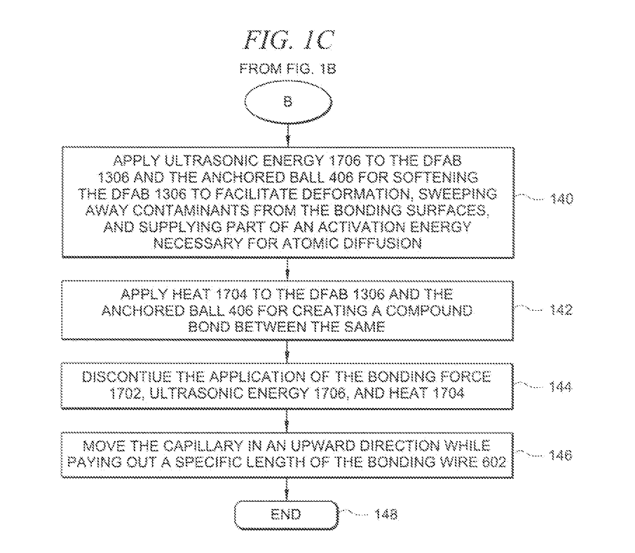

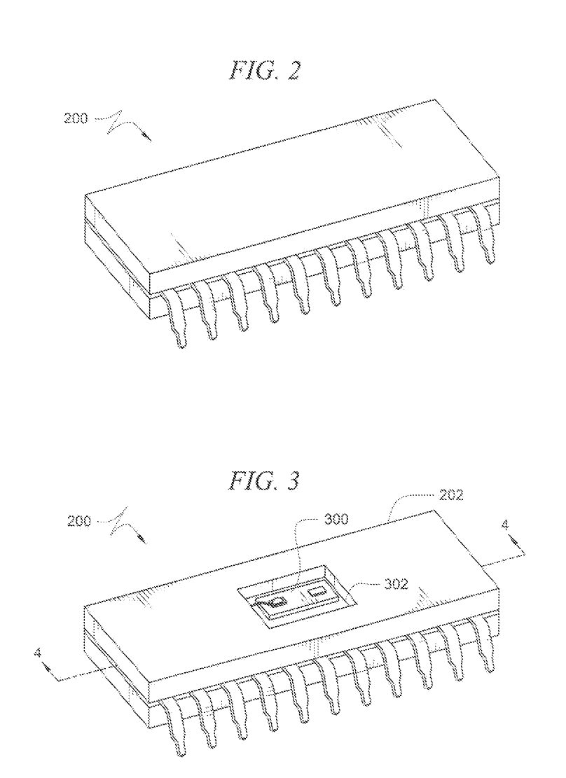

Referring now to FIG. 1A, there is provided a flow diagram of a method 100 for harvesting an IC die and creating wire interconnects that is useful for understanding the invention. As shown in FIG. 1 the method 100 begins with step 102 and continues with step 104. In step 104, a semiconductor integrated circuit (IC) is obtained. A perspective view of a semiconductor IC 200 is provided in FIG. 2. Semiconductor ICs 200 are well known to persons skilled in the art, and therefore will not be described in detail herein.

Referring again to FIG. 1A, the method 100 continues with step 106. In step 106, all or a portion of a protective plastic casing 202 is removed from the semiconductor IC 200. This step can involve using one or more chemical agents to remove the protective plastic casing 202. Such chemical agents are well known to persons skilled in the art, and therefore will not be described herein. A perspective view of the semiconductor IC 200 absent of a portion of the protective plastic casing 202 is provided in FIG. 3. As shown in FIG. 3, an IC die 300 is exposed in the area 302 where the protective plastic casing 202 has been removed.

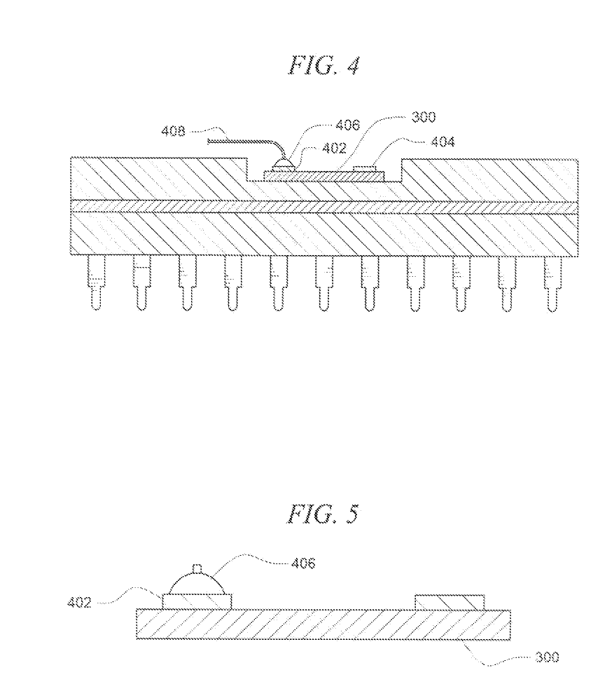

Referring again to FIG. 1A, the method 100 continues with step 108. In step 108, an interconnect wire coupled to the IC die 300 is cut so that the IC die 300 can be harvested. A cross-sectional view of the semiconductor IC 200 is provided in FIG. 4. As shown in FIG. 4, the IC die 300 is comprised of bond pads 402, 404 and one or more interconnect wires 408. Typically, an IC die 300 will include many bond pads 402 to which many interconnect wires 408 are attached. For convenience, FIG. 4 shows only one interconnect wire 408 attached to one bond pad 402. However, the invention is not limited in this regard. Each interconnect wire 408 is bonded to the bond pad 402 at an anchored ball 406. The bond pad 402 is comprised of a metal conductor, such as aluminum or copper. The interconnect wire 408 can be preferably cut slightly above the anchored ball 406. Wire cutting tools for cutting an interconnect wire 408 are well known to persons skilled in the art, and therefore will not be described in detail herein. However, it should be appreciated that any such wire cutting tool can be used without limitation.

Referring again to FIG. 1A, the method 100 continues with step 110. In step 110, the IC die 300 is harvested. A side view of a harvested IC die 300 is provided in FIG. 5. As shown in FIG. 5, the harvested IC die 300 is comprised of an anchored ball 406 bonded to the bond pad 402. The anchored ball 406 is comprised of a conductive material, such as aluminum, gold, copper or the like. The anchored ball 406 will typically have a size ranging from one and half (1.5) to four (4.0) times the diameter of the interconnect wire 408. The interconnect wire will generally have a diameter ranging from seven tenths (0.7) mils to three (3.0) mils. Still, it should be understood that the invention is not limited in this regard. Instead, larger or smaller wire sizes can be used. Similarly, the anchored balls can be larger or smaller than the values stated.

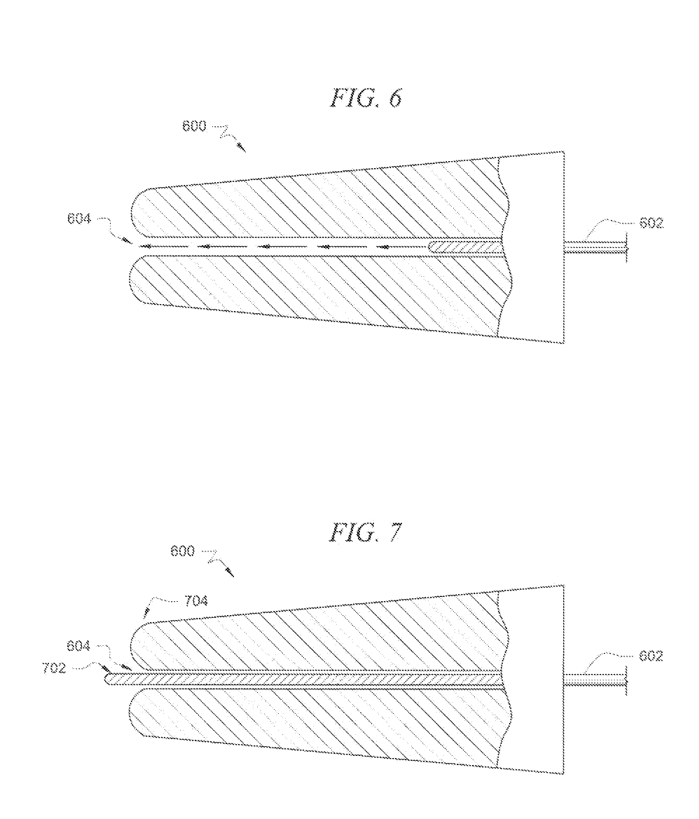

In step 112, a capillary is threaded. A schematic illustration of a capillary 600 being threaded is provided in FIG. 6. The capillary 600 is well known to persons skilled in the art. Therefore, the capillary 600 will not be described in great detail herein. However, it should be understood that the capillary 600 is comprised of an aperture 604 having a diameter greater than that of a bonding wire 602. The bonding wire 602 can have a diameter ranging from seven tenths (0.7) mils to three (3.0) mils.

As shown in FIG. 6, the bonding wire 602 is inserted into the aperture 604 during this threading process. It should be understood that the bonding wire 602 may be comprised of an elongated conductive material. The conductive material can be aluminum, gold, copper and alloys thereof. However, gold is preferable where it is intended for use in a complex, miniaturized circuit requiring high reliability. According to an embodiment of the invention, the bonding wire 602 is selected as a ninety nine and ninety nine hundredths percent (99.99%) gold bonding wire having a one and one tenths (1.1) diameter, a two (2) to six (6) percent elongation, and a break strength exceeding ten (10) grams. Still, the invention is net limited in this regard.

A side view of a threaded capillary 600 is provided in FIG. 7. As shown in FIG. 7, the threaded capillary 600 has a tail portion 702 of the bonding wire 602 protruding from an end 704 of the aperture 604. The tail portion 702 also extends away from the capillary 600. The tail portion 702 can have a length ranging between fifteen (15) to twenty (20) mils. Still, the invention is not limited in this regard.

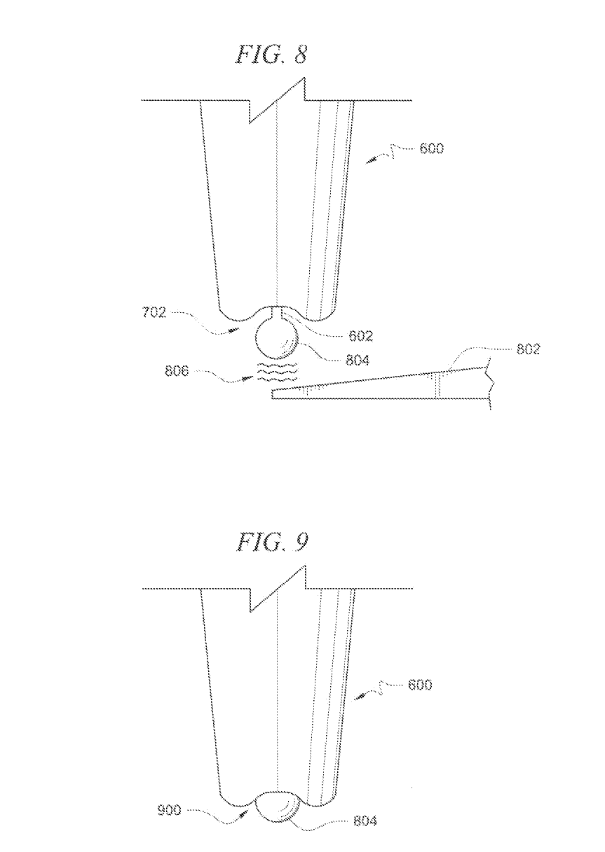

Referring again to FIG. 1A, the method 100 continues with step 114. In step 114, a free air ball (FAB) is formed at the tail portion 702 of the bonding wire 602. As shown in FIG. 8, the FAB 804 on the fail portion 702 of the bonding wire 602 is formed by placing an electric arc generator 802 a predetermined distance from the tail portion 702 of the bonding wire 602. The predetermined distance can include, but is not limited to, a distance having a value ranging between ten (10) to fifteen (15) mils. An electric arc is emitted between the tail portion 702 of the bonding wire 602 and the electric arc generator 802. The electric arc causes the tail portion 702 of the bonding wire 602 to melt and roll up into a ball. The tail portion 702 rolls up into a ball as a result of surface tension. In effect, the FAB 804 is formed. The size of the FAB 804 can he selected in accordance with a particular compound wire bonding application. For example, the FAB 804 has a size ranging between one and a half (1.5) to two and a half (2.5) times the diameter of the bonding wire 602. In this regard, it should be understood that the intensity and duration of the electric arc can be varied to adjust the size of the FAB 804.

According to an embodiment of the invention, the electric arc generator 802 is selected as a computerized flame-off (EFO) apparatus. As should be understood, the EFO apparatus creates an electrical spark. The electric spark melts the bonding wire 602 thereby forming the FAB 804. In this scenario, standard EFO parameters are used for forming the wire bond ball 804. Such EFO parameters are well known to persons skilled in the art. Therefore, EFO parameters will not be described in great detail herein. However, it should be understood that the EFO parameters include a spark gap parameter and an EFO discharge time parameter. The spark gap parameter is selected so that the spark gap has a size ranging between ten (10) to fifteen (15) mils. The EFO discharge time parameter is selected so that the duration of the electric arc has a value ranging between three (3) to six (6) milliseconds. Still, the invention is not limited in this regard.

Referring again to FIG. 1A, the method 100 continues with step 116. In step 116, the FAB 804 is captured and centered in a chamfered aperture of the capillary 600. A side view of a capillary 600 having a FAB 804 captured and centered in a chamfered aperture 900 is provided in FIG. 9.

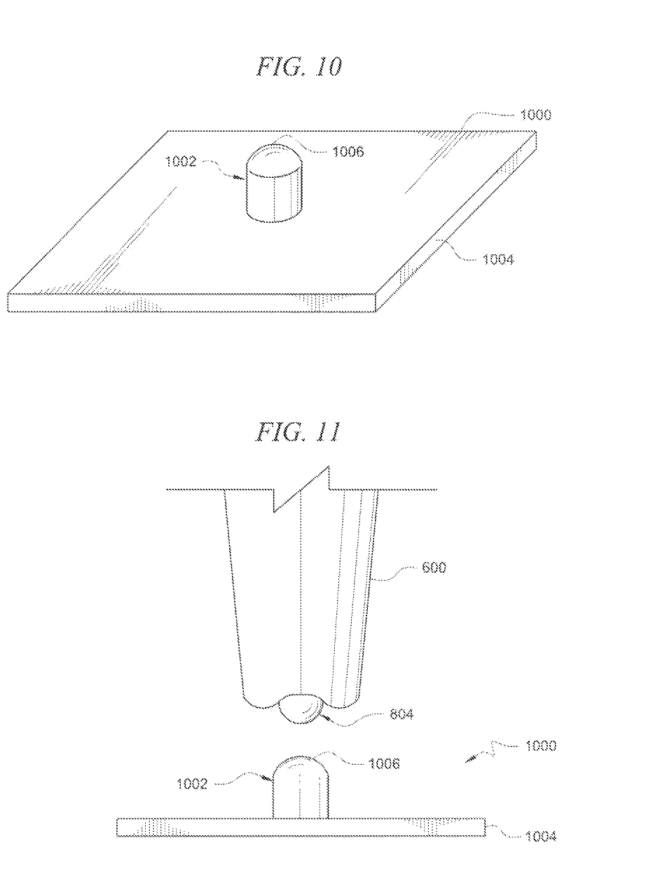

Referring now to FIG. 10, a tool 1000 is comprised of a rigid base structure 1004 formed of a rigid material suitable to withstand certain pressures and/or temperatures used in a wire bond ball preparation process as described herein. Such rigid materials include, but are not limited to, ceramic, copper, aluminum, and steel. According to an embodiment of the invention, the rigid base structure 1004 is formed of a 300 series stainless steel or a high density 99.99% alumina ceramic. Still, the invention is not limited in this regard.

As shown in FIG. 10, the tool 1000 is also comprised of a mold structure 1002. The mold structure 1002 can be a projecting relief defined by a three dimensional surface. The projecting relief is provided so that the FAB 804 can at least partially conform to its three dimensional surface when force and/or heat are applied thereto. The mold structure 1002 is advantageously designed to have a convex shaped upper portion (CSUP) 1006. The geometry of CSUP 1006 can be selected in accordance with a particular mold structure 1002 application. For example, the CSUP 1006 can be designed to provide a maximum contact area between a dimpled free air ball (described below in relation to FIG. 13) and an anchored ball 406 (described above in relation to FIG. 4) during a wire bonding process. In this regard, it should be noted that a single mold structure 1002 may not provide an optimum concave geometry for all wire bonding applications since the shape and size of anchored balls 406 may vary. Accordingly, mold structures 1002 having different CSUPs 1006 can be provided for all wire bonding applications or sets of wire bonding applications. The CSUP 1006 is preferably formed of a rigid material that will not form a solid state bond with a FAB 804 when pressure is applied thereto. The CSUP 1006 is also formed of a rigid material that will not form an atomic bond with a FAB 804 when heat is applied thereto. The mold structure 1002 can be formed of the same material or a different material as compared to the rigid base structure 1004.

In order to select a tool 1000 with a CSUP having optimum shape and geometry, it can be advantageous to measure a shape and size of an anchored ball 406 formed on the IC die. The IC die used in the process described herein can be manufactured by multiple suppliers using different manufacturing processes and equipment. Accordingly, the size and shape of the anchored balls can vary across a wide range of geometries. For reference, the size of the anchored balls typically ranges from 1.5 to 4.0 times larger than the diameter of the wire used to make the original bonds. The measurement of the anchored ball or balls can be obtained in step 118 using a high magnification optical measuring system or an automated bonder's vision system. These systems are well known to persons skilled in the art, and therefore will not be described in great detail herein.

In practice, it can be convenient to obtain size and shape measurements of the anchored ball 406 prior to beginning the wire bonding process. Consequently, a suitable tool 1000 can be selected in advance of such process and without interrupting the bonding operation. Experience has shown that anchored ball size and shape will generally remain consistent within a single IC die. Once the shape and size measurements are obtained, step 120 is performed where a tool is selected using the measurement values. In this regard, it should be understood that automated bonding system software can be programmed to access and obtain a preferred tool from a specified location.

Referring again to FIG. 1A, the method 100 continues with a step 122 of FIG. 1B. Referring now to FIG. 1B, the capillary 600 is moved in a horizontal and vertical manner until the FAB 804 is aligned with the mold structure 1002 of the tool 1000. A side view of a FAB 804 aligned with a mold structure 1002 of a tool 1000 is provided in FIG. 11. It should be understood that control of the capillary 600 can be automated to ensure a proper alignment of the FAB 804 and the mold structure 1002 throughout a wire bond ball preparation process. The wire bond ball preparation process can be defined by steps 122-132 of FIG. 1B.

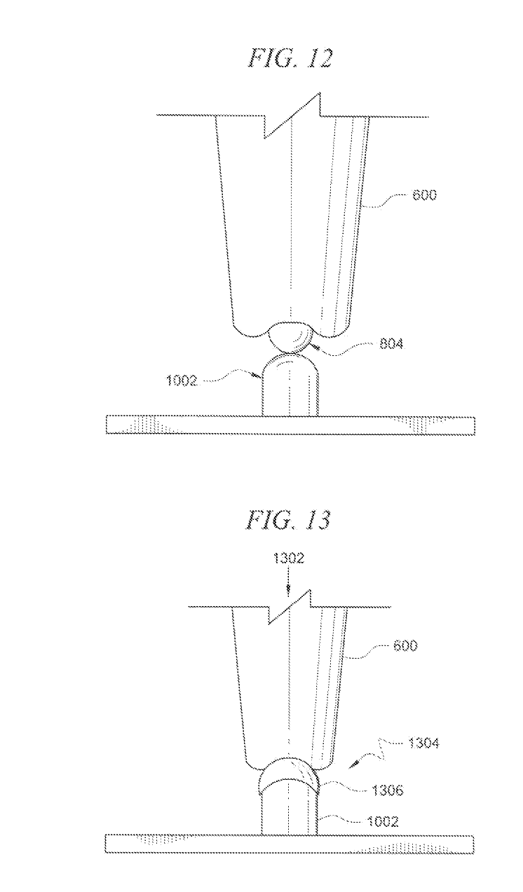

Referring again to FIG. 1B, the method 100 continues with step 124. In step 124, the capillary 600 is moved in a downward direction until the FAB 804 is in contact with the mold structure 1002. In this regard, it should be understood that the control of the capillary 600 can be automated. In such a scenario, the capillary 600 can be lowered using a preprogrammed decent rate. The capillary 600 can be lowered until the FAB 804 applies a particular contact force to the mold structure 1002. This contact force can be preprogrammed into the automated system. The contact force can be less than or equal to a molding force (described below in relation to FIG. 13). A side view of a FAB 804 in contact with a mold structure 1002 is provided in FIG. 12.

After step 124, step 126 is performed where a downward molding force is applied to the capillary 600. In this regard, it should be noted that a time delay can be provided between the application of an initial contact force and the application of a molding force. For example, this time delay can have a value between one tenth (0.1) of a millisecond and one (1) millisecond. The application of a downward molding force 1302 to a capillary 600 is illustrated in FIG. 13. The application of this molding force 1302 to the capillary 600 causes the FAB 804 to press against (i.e., apply a downward force to) the mold structure 1002. Subsequently, the method 100 continues with a step 128 where beat is optionally applied to the FAB 804. Application of the molding force 1302 and optional heat 1304 to an FAB is illustrated in FIG. 13. As shown in FIG. 13, the application of the molding force 1302 and/or heat 1304 result in a creation of a dimpled free air ball (DFAB) 1306. In this regard, it should be appreciated that the FAB 804 at least partially conforms to the mold structure 1002 when a molding force 1302 and/or heat 1304 are applied thereto. The intensity and duration of the molding force 1302 and/or beat 1304 control the degree of conformance of the FAB 804 to the mold structure 1002. Notably, modification of the FAB 804 in steps 124-128 provides a method 100 for improving the geometry of a wire bond interface surface absent of a die preparation requirement, such as a coining requirement and a ball shearing requirement. As such, these modification steps 124-128 eliminate the risk of damaging the harvested IC die 300 during preparation steps preceding a wire bonding process.

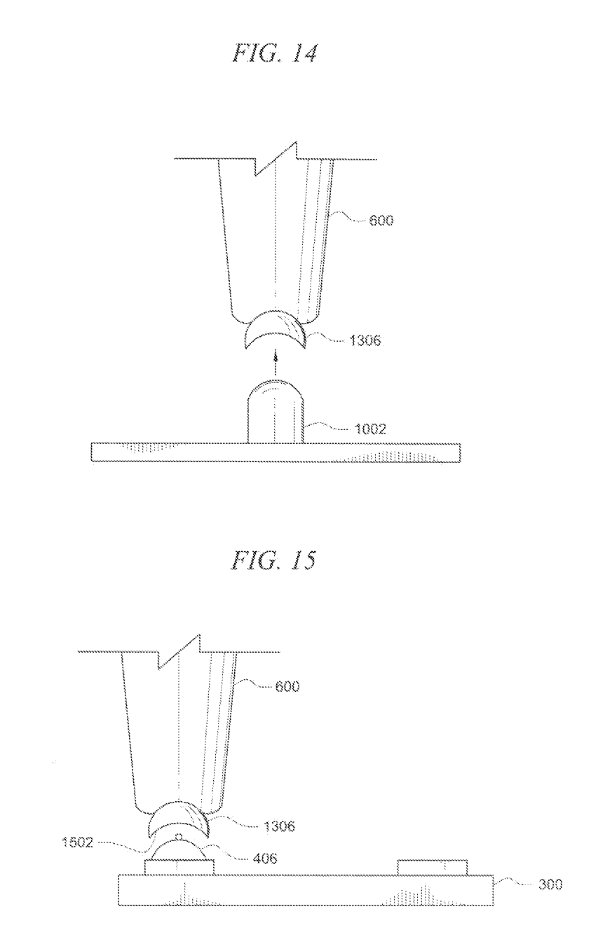

Referring again to FIG. 1B, the method 100 continues with a step 130. In step 130, the application of the molding force 1302 and/or heat 1304 to the DFAB 1306 is discontinued. Thereafter, step 132 is performed where the capillary 600 is moved in an upward direction so that the DFAB 1306 is removed from the mold structure 1002. A side view of a DFAB 1306 removed from the mold structure 1002 is provided in FIG. 14. After step 132, step 134 is performed. In step 134, the capillary 600 is moved in a horizontal and/or vertical manner until the DFAB 1306 is aligned with the anchored ball 406 of the harvested IC die 300. A side view of a DFAB 1306 aligned with the anchored ball 406 is provided in FIG. 15. It should be understood that control of the capillary 600 can be automated to ensure a proper alignment of the DFAB 1306 and the anchored ball 406.

As can be observed in FIG. 15, the concave bonding surface 1502 of the DFAB 1306 provides a relatively larger surface area for contacting the anchored ball 406 as compared to an unaltered FAB 804. As such, the larger surface area can provide a means for compensating for a misalignment between the DFAB 1306 and the anchored ball 406. Specifically, the larger surface area can negate equipment limitations and geometric inconsistencies of anchored balls 406.

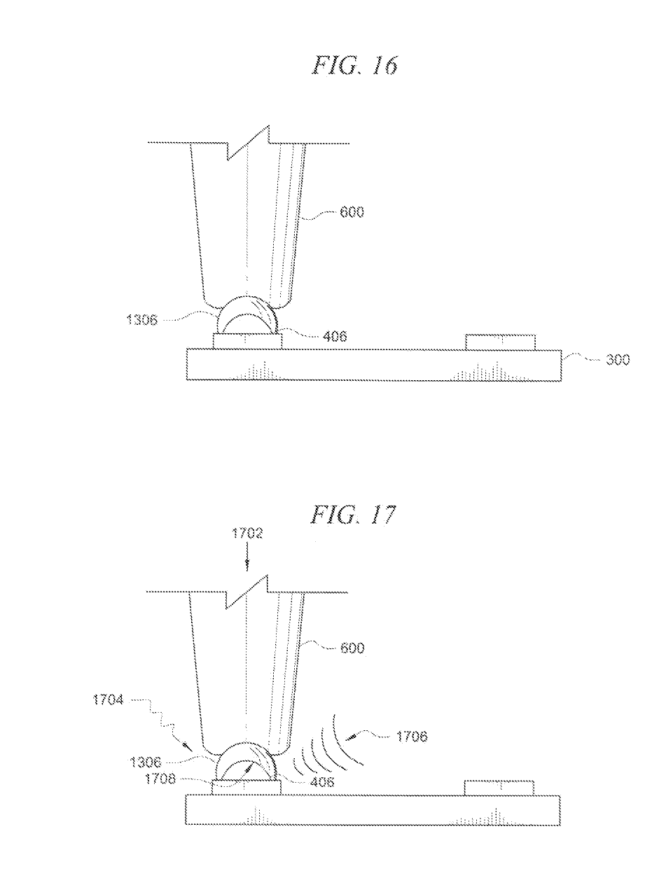

Referring again to FIG. 1B, the method 100 continues with a step 136. In step 136, the capillary 600 is moved in a downward direction until the DFAB 1306 is in contact with the anchored ball 406 of the harvested IC die 300. In this regard, it should be understood that the control of the capillary 600 can be automated. In such a scenario, the capillary 600 can be lowered using a preprogrammed decent rate. The capillary 600 can be lowered until the DFAB 1306 applies a contact force to the mold structure 1002. This contact force can be preprogrammed info the automated system. The contact force can be less than or equal to a bonding force (described below in relation to FIG. 17). A side view of a DFAB 1306 in contact with an anchored ball 406 is provided in FIG. 16.

After step 136, step 138 is performed where a downward bonding force is applied to the capillary 600. In this regard, it should be noted that a time delay can be provided between the application of an initial contact force and the application of the bonding force. For example, this time delay can have a value between one tenth (0.1) of a millisecond and one (1) millisecond. In FIG. 17, a downward bonding force 1702 is applied to a capillary 600. The application of this bonding force 1702 to the capillary 600 causes the DFAB 1306 to press against (i.e., apply a downward bonding force to) the anchored ball 406 of the harvested IC die 300. Subsequently, the method 100 continues with a step 140 of FIG. 1C.

Referring now to FIG. 1C, ultrasonic energy is applied to the DFAB 1306 and the anchored ball 406 in step 140. In this regard, it should be noted that a time delay can be provided between the application of a bonding force 1702 and the application of ultrasonic energy. For example, this time delay can have a value between one (1) and ten (10) milliseconds. It should also be noted that an automated ultrasonic device can be used to apply ultrasonic energy to the DFAB 1306 and the anchored ball 406. Automated ultrasonic devices are well known to persons skilled in the art, and therefore will not be described in great detail herein. However, it should be understood that conventional automated ultrasonic devices are available which operate from sixty kilo hertz (60 kHz) to one hundred thirty kilo hertz (130 KHz). According to an embodiment of the invention, the ultrasonic frequency is selected to lie in the one hundred ten kilo hertz (110 kHz) to one hundred thirty kilo hertz (130 KHz) range. Still, the invention is not limited in this regard.

Application of ultrasonic energy 1706 to the DFAB 1306 and the anchored ball 406 is illustrated in FIG. 17. As will be understood by those skilled in the art, the ultrasonic energy 1706 is maintained for a specified period of time defined by a time variable of a bonding process. The ultrasonic energy 1706 is provided for softening the DFAB 1306 to facilitate deformation of the same. The ultrasonic energy 1706 is also provided for sweeping away contaminants from a concave bonding surface 1502 (described above in relation to FIG. 15) of the DFAB 1306 and a bonding surface 1708 of the anchored ball 406. The ultrasonic energy 1706 is further provided for supplying part of an activation energy necessary for an atomic diffusion process. The atomic diffusion process is well known to persons skilled in the art, and therefore will not be described in great detail herein.

Referring again to FIG. 1C, the method 100 continues with a step 142. In step 142, heat is applied to the DFAB 1306 and the anchored ball 406 for creating a compound bond between the same. A schematic illustration of heat 1704 being applied to the DFAB 1306 and the anchored ball 406 is provided in FIG. 17. In this regard, it should be understood that the heat 1704 provides activation energy necessary for the atomic diffusion process. Notably, a relatively higher temperature is required when the ultrasonic energy 1706 is a low frequency (e.g., 60 kHz) ultrasonic energy. Conversely, a relatively low temperature is required when the ultrasonic energy 1706 is a high frequency (e.g., greater than 100 kHz) ultrasonic energy.

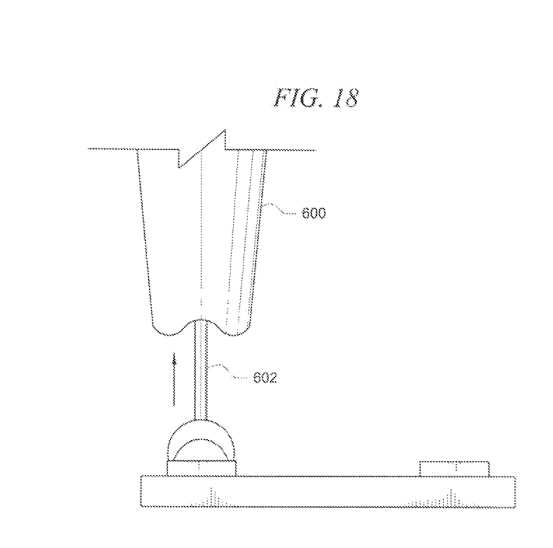

Referring again to FIG. 1C, the method 100 continues with step 144. In step 144, the application of the bonding force 1702 to the capillary 600 is discontinued. The application of ultrasonic energy 1706 and heat 1704 to the DFAB 1306 and the anchored ball 406 is also discontinued. Thereafter, step 146 is performed where the capillary 600 is moved in an upward direction while paying out a specific length of the bonding wire 602. As should be understood, the DFAB 1306 is permanently bonded to an anchored ball 406. A side view of a DFAB 1306 permanently bonded to an anchored ball 406 is provided in FIG. 18. Subsequently, step 148 is performed where the method 100 ends. Upon completion of method 100, an automated bonding system can continue by bonding an opposing end of the bonding wire 602 to another wire bonding site, if necessary.

According to an embodiment of the invention, the bonding wire 602 is selected to have a diameter of one and one-tenths (1.1) mil. The bonding wire 602 is also selected as a ninety nine and ninety nine hundredths percent (99.99%) gold bonding wire. The parameters for the wire bonding process are selected to have the following values.

| | |
|---|---|
| BONDING FORCE 1802 | 20 to 45 grams |
| TOTAL BONDING TIME | 15 to 40 milliseconds |
| ULTRASONIC MOTION | 20 to 50 microinches |
| IC DIE 300 SURFACE TEMPERATURE | 50° Celsius to 150° Celsius |

As should be understood, different automated bonding systems can be calibrated somewhat differently with regard to different settings for applied ultrasonic energy. In this regard, it should be noted that the ultrasonic motion parameter disclosed above reflects a total side-to-side motion of a tip of the capillary 600. As will be appreciated by those skilled in the art, this motion can be conveniently measured on any bonder using a laser measuring system.

All of the apparatus, methods and algorithms disclosed and claimed herein can be made and executed without undue experimentation in light of the present disclosure. While the invention has been described in terms of preferred embodiments, it will be apparent to those of skill in the art that variations may be applied to the apparatus, methods and sequence of steps of the method without departing from the concept, spirit and scope of the invention. More specifically, it will be apparent that certain components may be added to, combined with, or substituted for the components described herein while the same or similar results would be achieved. All such similar substitutes and modifications apparent to those skilled in the art are deemed to be within the spirit, scope and concept of the invention as defined.

We claim:

1. A method for creating a compound bond in a wire bonding process, comprising:
forming a free air ball at a first end of a bonding wire;
modifying a shape of said free air ball to at least partially conform to a shape of an anchored ball disposed on a bonding site; and
subsequent to said modifying step, bonding said free air ball to said anchored ball.

2. The method according to claim 1, further comprising determining at least one of a dimension and a shape of said anchored ball prior to said modifying step.

3. The method according to claim 1, wherein said modifying step comprises forming a concave surface on a portion of said free air ball.

4. The method according to claim 3, further comprising selecting a geometry of said concave surface based on a measured geometry of said anchored ball.

5. The method according to claim 1, wherein said bonding step further comprises applying a controlled force and ultrasonic energy to said free air ball.

6. The method according to claim 1, further comprising connecting a second end of said bonding wire to a substrate.

7. The method according to claim 1, further comprising selecting said bonding wire to include an elongated conductive material formed of gold.

8. The method according to claim 1, wherein said modifying step further comprises deforming said free air ball using a tool having a rigid surface.

9. The method according to claim 8, further comprising selecting said rigid surface to include a convex projection.

10. The method according to claim 8, further comprising selecting said tool based on a measuring step which includes determining at least one characteristic of said anchored ball selected from the group comprising a dimension of said anchored ball and a shape of said anchored ball.

11. The method according to claim 8, wherein said modifying step further comprises exposing said free air ball to an energetic stimulus to cause a heating of said free air ball.

12. The method according to claim 8, further comprising removing said free air ball from said tool subsequent to said deforming step.

13. A method for creating a compound bond in a wire bonding process, comprising:
forming a free air ball at a first end of a bonding wire;
determining at least one physical characteristic of an anchored ball disposed on a bonding site, said physical characteristic selected from the group comprising a size and a shape of said anchored ball;
modifying a shape of said free air ball to at least partially conform to said at least one physical characteristic; and
subsequent to said modifying step, bonding said free air ball to said anchored ball.

14. A method for creating a compound bond in a wire bonding process, comprising:
forming a free air ball at a first end of a bonding wire;
conforming a shape of at least one surface of said free air ball to approximate a surface contour of an anchored ball; and
subsequent to said conforming step, bonding said free air ball to said anchored ball.

15. The method according to claim 14, further comprising determining at least one of a dimension and a shape of said surface contour prior to said conforming step.

16. The method according to claim 14, wherein said conforming step comprises forming a concave surface on a portion of said free air ball.

17. The method according to claim 14, wherein said bonding step further comprises applying a controlled force and ultrasonic energy to said free air ball.
